(19) United States
(12) Patent Application Publication
(10) Pub. No.: US 2007/0128745 A1
(43) Pub. Date: Jun. 7, 2007

(54) Phosphor deposition method and apparatus for making light emitting diodes

(76) Inventors: Thomas J. Brukilacchio, Reading, MA (US); Charles A. Demilo, Marblehead, MA (US); David A. Doyle, Somerville, MA (US); Ryan C. Williamson, Somerville, MA (US)

Correspondence Address: FRANCIS J. CAUFIELD, 6 APOLLO CIRCLE, LEXINGTON, MA, 02421-7025, US

(21) Appl. No.: 11/291,369

(22) Filed: Dec. 1, 2005

(51) Int. Cl. H01L 21/00

(52) U.S. Cl. 438/22

(57) ABSTRACT

A phosphor deposition process and apparatus that enables an efficient, consistent, and flexible white light LED light engine by spraying a conformal coating of phosphor matrix onto an array of LEDs to achieve high color uniformity, consistency, and efficiency. A predetermined ratio of one or more phosphor powders are mixed with a support matrix (preferably silicone), the types and amounts of which are calculated to provide a predetermined spectral output. A low-viscosity carrier is introduced into the phosphor matrix to allow for further processing and deposition. The phosphor matrix and carrier mixture is atomized and sprayed in one or more uniform layers onto one or more LED devices. Computerized control, movable stages, and in-process spectral monitoring are incorporated to provide rapid and accurate processing of LED devices.

### FIELD OF THE INVENTION

This invention, in general, relates to the manufacture of light emitting diodes, and in particular, to apparatus and methods by which one or more thin homogeneous phosphor layers can be uniformly applied to LED chips to control the color, brightness, and variability of radiation they emit

### BACKGROUND OF THE INVENTION

Unacceptable color consistency and uniformity are significant problems within the high brightness LED market because of the methods by which such LEDs are manufactured. The most common method for making white light from an LED is by the deposition of phosphor onto a blue LED. When excited by a specific frequency of light, the phosphor has a broadband fluorescence emission into the green, yellow, and potentially, red regions of the light spectrum. The combination of blue light from the LED in conjunction with the emission spectrum from the phosphor results in white light. For example, U.S. Pat. Nos. 5,813,753 and 5,998,925 disclose light emitting devices in which a blue LED is disposed in a reflective cup and surrounded by material including phosphors. If the phosphor is not excited uniformly by the blue light from the LED, the resultant emission can have substantial color variation. This effect occurs because of a non-uniformity in the thickness of the phosphor-containing material surrounding the LED and consequent spatially non-uniform absorption of blue light and emission of red and green light. If the thickness of the phosphor is not closely controlled, the color temperature of the white light can have large deviations from nominal.

Conventional techniques for depositing phosphor on an LED assembly mainly consist of combining the phosphor with an epoxy-based encapsulant, then either photo curing or heat-curing the encapsulant. The deposition method of the phosphor-encapsulant mix typically involves pushing the material through a syringe onto the LED. During processing (mixing, deposition, curing), the phosphor particles inconsistently settle within the mixture, leading to a large amount of variability in white light spectrum from unit to unit. Additionally, the phosphor-encapsulant thickness is typically on the order of the die thickness or greater. Light exiting substantially normal to the die surface has a different path length relative to light exiting the die at increasing angles from the normal. This results in both color and intensity nonuniformities thereby reducing the utility of the light source for demanding applications.

It is therefore a primary object of the invention to provide methods and apparatus for manufacturing LEDs that emit bright and spectrally uniform light.

It is another object of the invention to provide methods and apparatus for uniformly depositing a homogeneous mixture containing phosphor on a LED assembly.

It is yet another object of the invention to provide a fast and efficient method for uniformly depositing homogeneous matrix of phosphor on LED arrays.

It is yet another object of this invention to provide LEDs that emit white light.

Still another object of this invention is to provide LEDs that emit green light.

Other objects of the invention will, in part, be obvious and will, in part, appear hereinafter, when reading the following detailed description in connection with the drawings.

### SUMMARY OF THE INVENTION

This invention provides apparatus and methodology for uniformly depositing a homogeneous matrix containing light converting materials such as phosphors or quantum dots onto an LED or LED array so that the resulting LED assemblies emit light in a substantially spectrally uniform manner. The method includes mixing predetermined ratios of powder, e.g. phosphor or quantum dots, in a support matrix that holds and maintains the powder such that it is distributed uniformly within it.

A carrier is then introduced into the phosphor powder matrix to decrease the viscosity of the mixture for further processing (e.g. pumping through distribution channels).

The lower viscosity mixture is then deposited onto LEDs by atomizing and spraying the mixture in one or more uniform thin layers.

The type and amounts of phosphor powder within the matrix and number of layers applied to the LED(s) are predetermined so that the LED(s) emit light of predetermined spectral properties. In one aspect of the invention, the mixture and number of layers are applied such that the LED(s) emit substantially uniform white light.

In an aspect of the invention, the mixture of carrier and phosphor matrix is repeatedly agitated after mixing and prior to deposition to maintain the homogeneity of the phosphor matrix and carrier mixture.

In another aspect of the invention, after deposition onto the LED(s), the one or more thin layers of phosphor are encapsulated onto the LED(s) with a thin transparent material that keeps the phosphor matrix layer(s) substantially stable and stationary on the LED(s).

In yet another aspect of the invention adapted for batch processing of LED arrays, the position of the LED arrays is actuated in an automated manner with respect to the deposition components and process.

### BRIEF DESCRIPTION OF THE DRAWINGS

The structure, operation, and methodology of the invention, together with other objects and advantages thereof, may best be understood by reading the following detailed description in connection with the drawings in which each part has an assigned numeral or label that identifies it wherever it appears in the various drawings and wherein:

FIG. 1 is a high level flow chart of an embodiment of the inventive method;

FIG. 2 is a simplified diagrammatic plan view of a mixing and distribution network according to an embodiment of the inventive apparatus;

FIG. 3 is a diagrammatic partially sectioned, elevational view of an apparatus used in the network of FIG. 1 to agitate the phosphorous matrix and carrier mix;

FIGS. 4A and 4B are diagrammatic cross sectional views of a spray nozzle head for depositing the low-viscosity phosphorous matrix and carrier mix;

FIG. 5 is a diagrammatic perspective view of a batch-processing translation stage and phosphor deposition head;

FIG. 6A is a diagrammatic elevational view of a strip light carrying groups of LEDs for batch processing and FIG. 6B shows an enlarged view of a segment of the translation stage of FIG. 6A;

FIG. 7 is a simplified diagrammatic perspective of a translational stage batch-processing embodiment including post deposition dryers;

FIG. 8 is a diagrammatic perspective view of the use of a rotary translation stage in conjunction with a spectral analyzer for batch processing;

FIG. 9 is a graph showing how the color temperature of a characteristic LED varies as a function of relative thickness of a phosphor containing layer deposited in accordance with the invention; and

FIG. 10 is a graph showing the variation of light emitted from a blue LED coated with green phosphor layers of different relative thicknesses.

### DETAILED DESCRIPTION

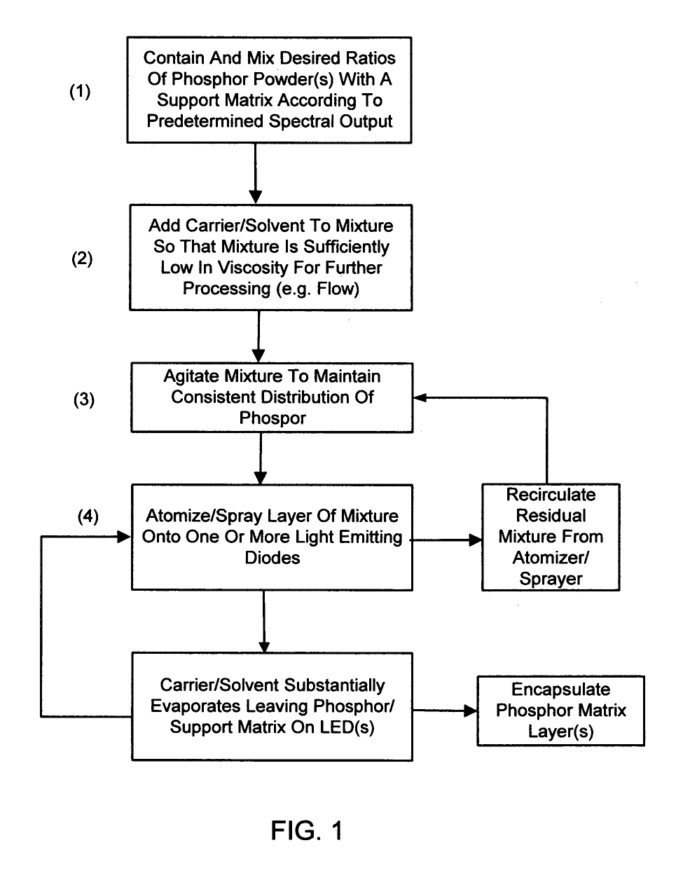

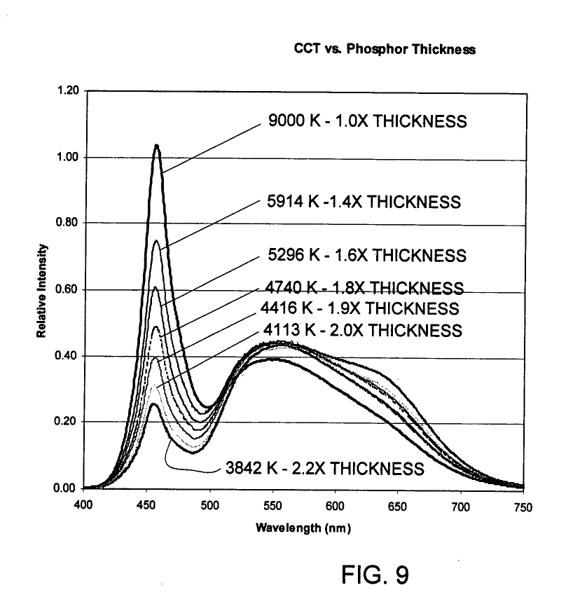

The present invention relates to apparatus and methods for depositing homogeneous mixture of a matrix and preselected phosphor powder mixture as a uniform layer on an LED chip to reduce variability in the color of radiation emitted by the resultant LED assembly. The structure and properties of the final LED product using the inventive methodology also forms part of the invention. The methodology may best be understood by now referring to FIG. 1 which identifies various high level steps practiced in implementing the method of the invention. The steps are generally carried out at ambient or room temperature. The first step is to contain and mix predetermined amounts of one or more phosphor powders associated with a predetermined spectral output when deposited on a specific LED device. To produce substantially white light with, for example, a 460 nm LED with a 30 nm bandwidth (FWHM), yellow emitting Yitrium Aluminum Oxide:Cerium powder is combined with red emitting Calcium Sulphide:Europium powder, respectively, in an approximately 9:1 ratio by mass for fluorescent lights and a ratio of 6:1 by mass for incandescent lights. For purposes of atomization in a later step of the process, the approximate particle size of the Yitrium Aluminum Oxide is 4.0 μm and that of the Calcium Sulphide is 5.5 μm. As is discussed further below, the mixture is also applied in sufficient thicknesses to produce the desired spectral characteristics (See FIG. 9). The powder(s) are mixed in a support matrix that suspends the materials in a substantially uniform manner so that the phosphor powders are homogeneously distributed throughout it. It may be desired to make the matrix very dense to minimize differences in color according to the angle of perspective, a problem earlier referenced with respect to certain prior art methods.

The support matrix material is selected so that it functions appropriately during the remaining steps of the deposition process, does not interfere with the spectral characteristics of the LED device, and also remains stable at the LED's operating temperature. An example of such material is NuSil Silicone Elastomer R-2615 (10:1 silicone to hardener mix), which remains soft when mixed with the phosphor powders, is optically clear, and is not adversely effected at the operating temperature of the 460 nm LED previously referenced. The support matrix prevents migration of the phosphor powders within the matrix. NuSil Silicone has a viscosity on the order of five to ten thousand centipoises.

The second major step of the method is to add a carrier to the mixture to make it of sufficiently low viscosity for further processing, allowing it to be distributed within the deposition system and finally deposited in spray form on the LED device(s). The preferred carriers are preferably powerful solvents, such as Xylene, added in sufficient amounts to make the phosphor matrix and carrier mixture close in viscosity to the carrier itself.

To keep the phosphor matrix evenly distributed within the mixture, the third major step of the inventive process is to agitate the mixture until it is ready for deposition. In an embodiment of the invention, the phosphor matrix and carrier mixture is distributed into a fluid cup (see FIG. 3 and accompanying description) in which it is continuously agitated prior to deposition.

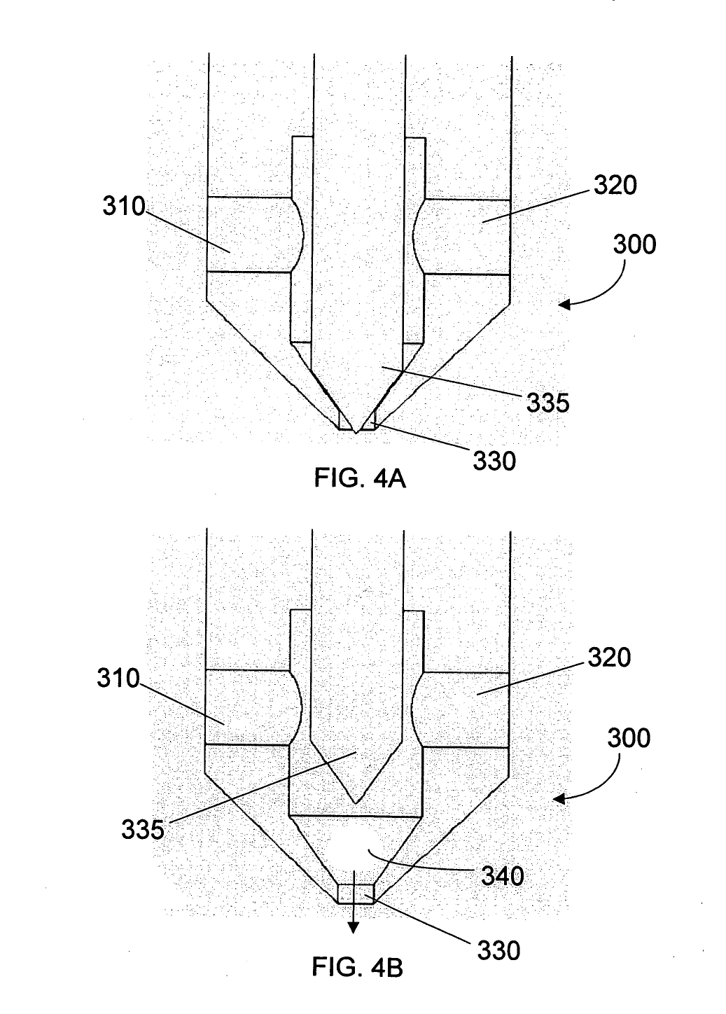

The fourth major step of the inventive process is to atomize and spray the atomized mixture of phosphor matrix and carrier onto an LED assembly in one or more layers. The number of layers depends on the characteristics of the phosphor mixture and desired spectral output of the device. This step may be accomplished with a spray head (such as that described in relation to FIGS. 4A-4B). During and after spray deposition, the carrier substantially evaporates, leaving the phosphor matrix on the LED assembly. The drying process for each layer occurs very quickly so that little time need elapse between the application of successive layers. However, if more rapid drying is needed, use may be made of dryers (see FIG. 6 and accompanying description). Additionally, to aid in preventing migration/degradation of the phosphor layer and maintain chromatic consistency, an encapsulating layer may be applied, preferably composed of a thin layer of silicone and matrix hardener. A small amount of encapsulant migrates into the original matrix to promote additional hardening of the matrix, and the remaining portion cures to form a hardened silicone “shell” over the matrix.

The matrix also increases the light extraction efficiency from the LED chip because the silicone material of which it is composed has an index of refraction (1.41) greater than that of air and closer to the index of refraction of the LED substrate (2.40 in the case of Gallium Nitride based LEDs). Also, the phosphor layers deposited in this manner conform more closely to the shape of the chip thereby not altering the apparent size of the emitting area thus resulting in brighter LEDs with desired spectral outputs possible compared with other processes that do alter the apparent size of the emitting area while trying to achieve preferred colors.

In a particularly preferred process, the yellow and red phosphors are preferably mixed and applied independently. The reason for this is that the density of the yellow phosphor vs. the red phosphor is different, so it is easier to maintain a homogeneous matrix by first depositing the yellow phosphor, and then depositing the red phosphor to keep the phosphors from potentially otherwise separating. This approach produces much more controllable and consistent results than if two phosphors of differing density are mixed and applied together.

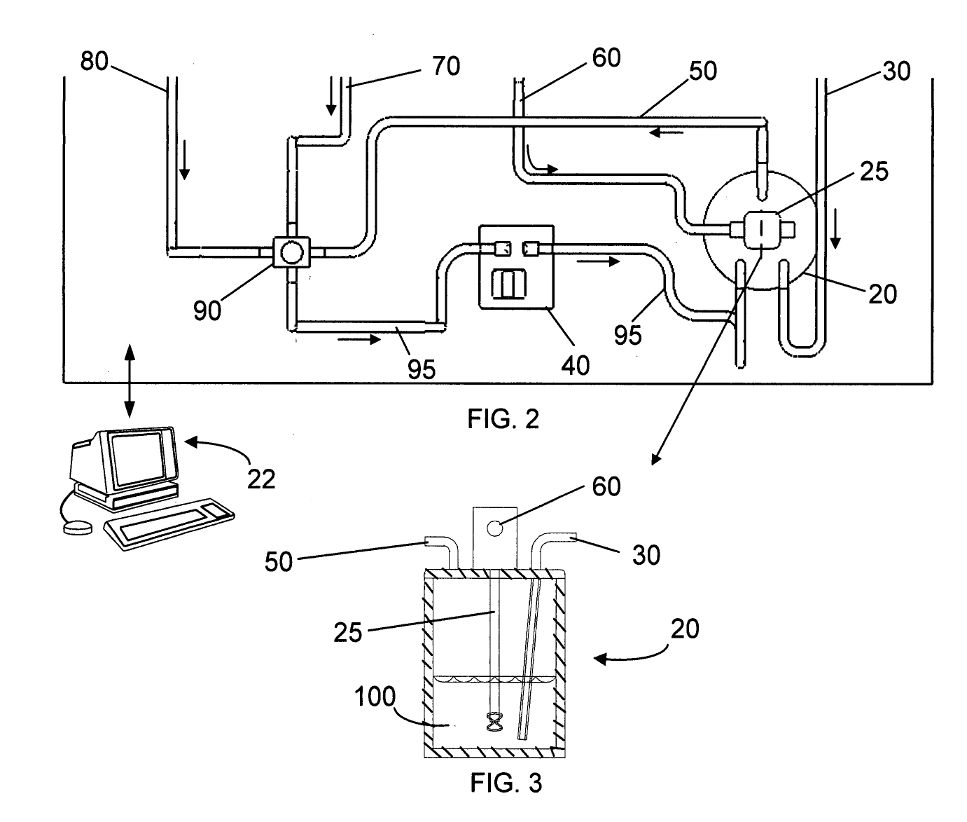

To improve the efficiency and uniformity of the deposition process, a step may be added (further described in reference to FIG. 2) to recirculate undeposited mixture back through the system. This prevents clogging or settling of the phosphorous matrix when it is not being atomized/sprayed.

Now referring to FIG. 2, there is shown a deposition distribution network according to an embodiment of the invention. As seen, the deposition network comprises a fluid cup 20 that receives and mixes the deposition mixture materials described in relation to the steps 1 and 2 of FIG. 1 (including phosphor powder(s), the support matrix, and carrier). An agitator 25, for example, is activated through pressure via an air pressure line 60 to maintain the consistency of the deposition mixture in accordance with step 3 of FIG. 1. A further detailed representation of fluid cup 20 is shown in FIG. 3, showing a deposition mixture 100 in cup 20.

Referring still to FIG. 2, prior to the deposition process, phosphor mixture 100 (shown in FIG. 3) in cup 20 is forced by an air pressure line 30 through a fluid line 50 and then to a spray head 90. Spray head 90 (see FIGS. 4A & 4B) includes a spray nozzle 300, which deposits an atomized mixture onto LED device(s) (as described in further detail below). While the deposition mixture flows into spray head 90 through line 50, pressure through air pressure line 70 also activates spray nozzle 300, which atomizes and sprays the deposition mixture (see FIGS. 4A-4B and accompanying description). Unused residual deposition mixture is pumped back into fluid cup 20 through a fluid line 95 by a pump 40 which helps prevent particulate settling of the phosphor(s) at all points throughout the circulation loop.

Again referring to FIGS. 4A-4B, spray nozzle 300 includes a phosphor deposition mixture intake 310 coupled with and fed by fluid line 50 (shown in FIGS. 2-3). Once the phosphor mixture reaches spray nozzle 300, pressure from air pressure line 70 forces needle 335 to rise (as shown in FIG. 4B) and release pressure through needle valve 330. Pressurized air from pressure line 70 atomizes the phosphor mixture into a fine mist 340, which is then forced out of needle valve 330 and deposited onto an LED device (not shown) in accordance with the 4^{th} major step of the inventive process as described above. Atomization may occur either inside the nozzle head or outside of it. Unused residual phosphor mixture is sucked into outlet 320 and pumped through fluid line 95 by a pump 40 back into fluid cup 20 (as shown and described according to FIG. 2).

In an embodiment of the invention, the deposition system of FIGS. 2-4 can be modified to include a separate fluid cup, fluid line, and nozzle (none of which are shown) for encapsulant deposition. Deposition of the encapsulant is accomplished using the same basic technique (atomized spraying) used for phosphor deposition. A pump and re-circulation circuit is not required for encapsulant deposition as there is no concern with phosphate particulate settling within the encapsulant solution. As will be understood, the process described above may be readily automated under the control of a computer 22 programmed in a well-known manner to assist in carrying out the sequence of steps of the method in an orderly and coordinated fashion including controlling events in the method, taking measurements and providing instructions. Computer 22 may also be used to provide a user interface, collect, manage and reduce data, and otherwise conduct general housekeeping functions.

In addition, the above described deposition system may include ultrasonic transducers in the flow lines to ensure that the matrix remains homogenous, and heat may be introduced into the delivery lines and other elements of the circulatory system to aid in the evaporation of the carrier.

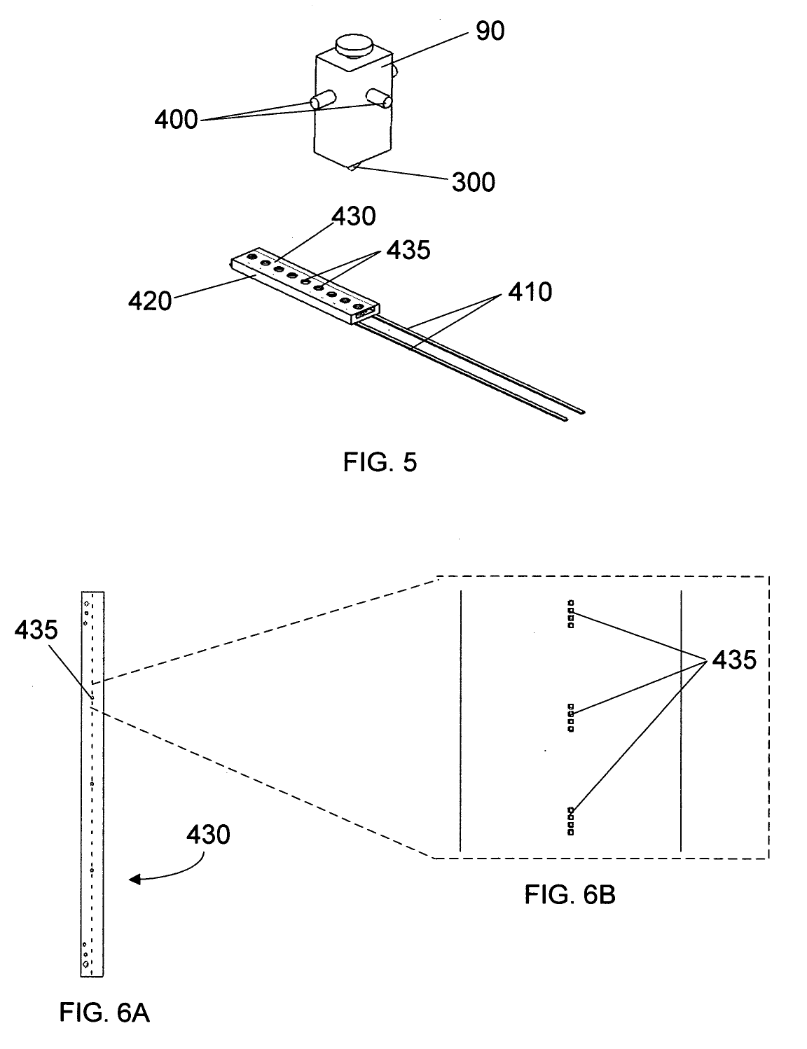

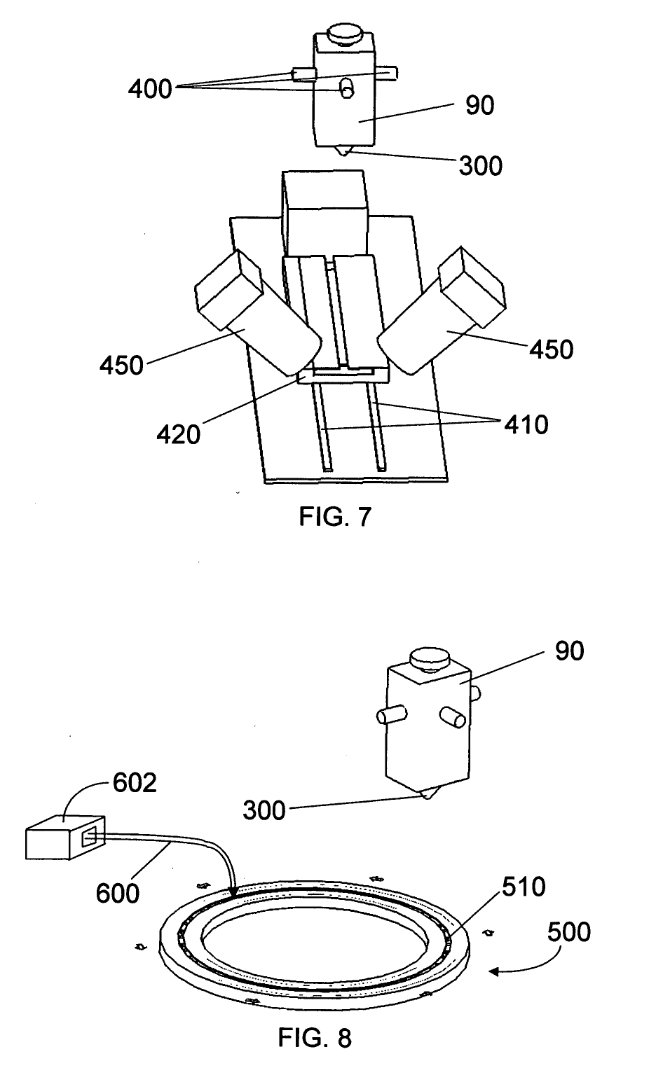

Reference is now made to FIGS. 5 and 7 that show apparatus for depositing phosphor layers using batch processing. As seen in FIG. 5, spray head 90 with spray nozzle 300 is shown positioned above a strip light 430 of LED devices 435 carried on a linear translation stage 420 for batch processing. Translation stage 420 moves along tracks 410 in automated coordination with the deposition of phosphor spray from spray head 90. To achieve a high degree of uniformity within the strip light 430, batch processing is readily accomplished with the aid of a programmed central processing device (not shown) connected to various inputs and outputs (not shown) to and from translation stage 420 and spray deposition components. Various fluid and air lines 400 are connected to spray head 90 in accordance with embodiments described above.

FIGS. 6A and 6B illustrate how LED devices are arranged on the linear translation stage 420 for batch processing. FIG. 6B shows an enlarged view of a segment of strip light 430 with LED devices 435. As seen in FIG. 6B LED, devices 435 are arranged in separated groups, each group of which is processed substantially simultaneously. By way of example, LEDs have been made from a 10-inch strip that included 144 chips arranged in 36 groups of 4 each.

Reference is now made to FIG. 6 which shows an embodiment of the invention for batch processing that includes dryers 450 to assist in the evaporation of carrier within the phosphor mixture or curing of encapsulant on the LED devices.

In alternative embodiments, batch processing may be accomplished with other types of stage arrangements. For example, rotary stages are possible as shown in FIG. 7 where spray head 90 is positioned relative to a rotary stage 500 holding LED array device 510. In other alternative embodiments, the LED array devices can be held stationary and spray head 90 translated and actuated in relation to it.

Alternative embodiments may also include an in-process spectral monitoring system as shown in FIG. 8 to provide feedback for tighter control. For example, an optical fiber pick-up 600 is coupled with a spectrophotometer 602 is positioned to view and analyze the spectral output of specific regions of LED devices in between deposition of phosphor matrix layers. Data from the analyzer is used to determine when a sufficient number of sprayed on layers have been deposited to achieve the required spectral properties.

Whether processed separately or in one of the described batch processes, the color temperature of an LED can be adjusted in a controllable manner by suitably adjusting the thickness of the phosphor containing layer. FIG. 9 shows that the color temperature varies directly as a function of the thickness of the deposited layer; the thicker the layer the lower the color temperature. Of course, such curves will vary for a given LED chip and the material composition of the matrix and phosphor powder composition. However, curves like that of FIG. 9 can be developed for each LED chip and matrix phosphor mix composition to control thickness in a predetermined manner. This may also be done in automated fashion by measuring color temperature on-line after a layer has been deposited and then supplying feed back information to proceed with another layer of predetermined thickness to arrive at the desired result. Thickness can, of course, be related to process control parameters.

Examples of white LED devices manufactured in accordance with the invention comprise LED linear arrays available in lengths of 4-inches and 10-inches with input powers ranging from 3-15 Watts and other properties as set forth in the following table:

| | | Rated | | | | |
|---|---|---|---|---|---|---|
| Length | Forward | Current | Luminous Flux | Color Temperature | | |
| (Inches) | Voltage (V) | (A) | (Lumens) | Min | Typical | Max |
| 10 | 16 | 0.95 | 296 | 4100 | 4300 | 4500 |
| 10 | 16 | 0.45 | 148 | 4100 | 4300 | 4500 |
| 4 | 16 | 0.35 | 112 | 4100 | 4300 | 4500 |
| 4 | 16 | 0.20 | 65 | 4100 | 4300 | 4500 |

The foregoing white LEDs were achieved by applying yellow and red phosphors to blue emitting LEDs as described earlier.

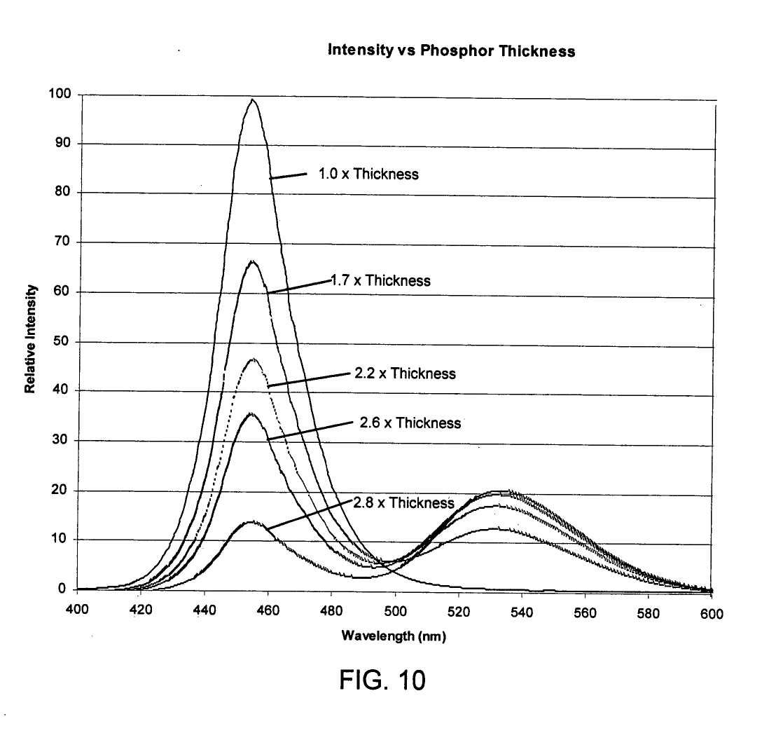

An example of a green emitting LED was achieved by starting with a blue LED at approximately 460 nm, and coating the LED with a phosphor that emits green light when excited by the blue light. A typical green phosphor has the following chemical composition: SrGa₂S₄. FIG. 10 is a graph showing the relationship between the thickness of the green phosphor and the green light vs. blue light emission. The ideal deposition produces a layer of the optimal thickness such that the quantity (intensity) of green light is maximized. Obviously, the blue emission is filtered out in accordance with the thickness of the green phosphor layer applied as illustrated in FIG. 10.

Having described the invention with reference to particular embodiments, other variations will occur to those skilled in the art based on its teachings. For example, any of the batch processing arrangements can also readily be automated and controlled via computer 22 as previously described. The inventive phosphor deposition process can also be applied to LEDs that emit in the UV. With a UV chip, different phosphors are used, but the concept remains the same. Additionally, the inventive deposition process can be used with a class of light converting materials known as quantum dots, such as those marketed by Evident Technologies, 216 River Street, Suite 200, Troy, N.Y. 12180. The efficiency of quantum dots is currently low, but quantum dots have the potential to replace phosphors for LED light conversion. In powder form, they can be used in the inventive deposition process much the same as the phosphors, but would have the advantage of being tunable because they are based on semiconductor nanocrystals that are designed to translate light of one wavelength into light of another wavelength, allowing them to act as both filters and converters. Thus, quantum dots would substitute for the phosphor powder in the foregoing process. Therefore, it is intended that all such variants be within the scope of the invention as defined by the claims.

What is claimed is:

1. A method of depositing uniform layers of a matrix containing light converting materials onto light emitting diode chips, said method comprising the steps of:
mixing at least one powder of a light converting material in a support matrix to provide a homogeneous mixture having a substantially uniform distribution of said material throughout;
introducing a carrier into said mixture of light converting material and support matrix to reduce the viscosity of said mixture for further processing;
atomizing said mixture; and,
depositing one or more layers of said mixture onto at least one light emitting diode chip to form at least one substantially uniform matrix layer containing said light converting material.

2. The method of claim 1 wherein said light converting materials are selected from the group consisting of phosphor and quantum dot powders.

3. A method of depositing uniform layers of a phosphor containing matrix onto light emitting diode chips, said method comprising the steps of:
mixing phosphor powder in a support matrix to provide a homogeneous mixture having a substantially uniform distribution of phosphor throughout;
introducing a carrier into said mixture of phosphor and support matrix to reduce the viscosity of said mixture for further processing;
atomizing said mixture; and,
depositing one or more layers of said mixture onto at least one light emitting diode chip to form at least one substantially uniform phosphor matrix layer.

4. The method of claim 3 wherein said mixing step comprises independently mixing more than one phosphor powder in a support matrix and depositing the resultant mixtures sequentially.

5. The method of claim 3 wherein said phosphor powders are selected from the group consisting of yellow, red, and green phosphors.

6. The method of claim 5 wherein said phosphors comprise Yitrium Aluminum Oxide:Cerium powder, Calcium Sulphide:Europium powder, and SrGa₂S₄.

7. The method of claim 3 further including the step of encapsulating said phosphor matrix layer on said light emitting diode chip so that the phosphor matrix layer remains substantially stable and stationary.

8. The method of claim 3 wherein said phosphor powder and said support matrix are combined in predetermined proportions to provide said light emitting diode chip with predetermined spectral properties.

9. The method of claim 8 wherein said predetermined spectral properties vary in accordance with the thickness of said phosphor powder and support matrix layer for a given light emitting diode chip and mix composition.

10. The method of claim 8 wherein the predetermined proportions of phosphor powder and the number of layers deposited are calculated to produce white light when said light emitting diode is substantially blue.

11. The method of claim 3 wherein said support matrix is optically clear and remains stable at said light emitting diode's operating temperature.

12. The method of claim 11 wherein said support matrix is a silicone based elastomer.

13. The method of claim 12 wherein said support matrix has a viscosity on the order of five to ten thousand centipoises.

14. The method of claim 3 wherein said carrier is a solvent.

15. The method of claim 14 wherein said solvent is Xylene.

16. The method of claim 3 further including the step of:
agitating the mixture of carrier, phosphor, and support matrix prior to atomization to maintain a uniform distribution of phosphor within said mixture.

17. The method of claim 16 further including the step of during and after deposition, recirculating any remaining mixture to maintain a uniform distribution of phosphor within said mixture.

18. The method of claim 3 further comprising the steps of automatically moving and actuating a spray head relative to said one or more light emitting diodes in coordination with the deposition of said phosphorous mixture.

19. The method of claim 3 wherein the relative movement of said spray head and said light emitting diodes is carried out with at least one drivable mechanism comprising a linear translation stage and where the light emitting diodes are placed on said linear translation stage and are driven in relation to said spray head.

20. The method of claim 3 wherein the relative movement of said spray head and said light emitting diodes is carried out with at least one drivable mechanism comprising a rotary translation stage and where the light emitting diodes are placed on said rotary translation stage and are driven in relation to said spray head.

21. The method of claim 3 further comprising the step of analyzing the spectral output of one or more light emitting diodes after deposition of one or more layers of phosphor matrix.

22. The method of claim 3 further comprising the step of directing dryers at the one or more phosphor matrix layers deposited on a light emitting diode to aid in the evaporation of carrier within the one or more layers of phosphor matrix.

23. A method of depositing uniform layers of a phosphor containing matrix onto light emitting diode chips, said method comprising the steps of: mixing one or more phosphor powders in predetermined proportions so that the powder mixture has predetermined spectral properties;
mixing said one or more phosphor powders with a support matrix of sufficient viscosity to provide a homogeneous mixture in which said phosphor remains uniformly distributed within the mixture;
further mixing a carrier in said mixture to provide a thinned mixture of reduced viscosity that may be handled substantially as a liquid and wherein said carrier evaporates upon atomization;
pouring said thinned mixture into a fluid cup and agitating it to prevent said phosphor powders from settling within the cup;
pressurizing said cup and forcing said thinned mixture to flow to an atomizer;
atomizing said thinned mixture and directing said atomized thinned mixture onto a light emitting diode-to cause said carrier to evaporate while depositing one or more phosphor matrix layers on said light emitting diode;
recirculating residual undeposited thinned mixture back to said cup and said agitator to prevent phosphor from settling within said mixture;
encapsulating the one or more phosphor matrix layers on said light emitting diode so that the one or more phosphor matrix layers remain substantially stable and stationary.

24. An apparatus for depositing one or more layers of phosphorous matrix onto a light emitting diode, said apparatus comprising:
a fluid cup for receiving and mixing predetermined amounts of:
phosphorous powders matrix material for suspending said phosphorous powder within it, and carrier solution for lowering the viscosity of the phosphorous mixture to a fluid-like state;
an agitator connected with said cup for agitating the phosphorous mixture to maintain a substantially consistent distribution of phosphor powder within said mixture;
a first air pressure supply line and fluid discharge line connected to said fluid cup where pressure from said first air pressure supply line forces said phosphorous mixture out through said fluid discharge line from said fluid cup;
a spray head for depositing said phosphorous mixture onto a light emitting diode, said spray head connected to said fluid cup by said fluid discharge line, said spray head having a spray nozzle for completing deposition of said phosphorous mixture by atomizing and spraying it onto the light emitting diode.

25. The apparatus of claim 22 further comprising a recirculation fluid line and recirculation pump connected between said spray head and said fluid cup for pumping residual phosphorous mixture from said spray head back into said fluid cup.

26. The apparatus of claim 22 further comprising an in-process spectral monitoring system positioned to analyze the spectral output of one or more light emitting diodes before and after depositing each of the layers of phosphorous matrix.

27. The apparatus of claim 22 wherein said agitator comprises a nozzle that extends into said fluid cup and a second air pressure supply line connected to said nozzle for providing pressurized air to agitate phosphorous mixture within said fluid cup.

28. At least one light emitting diode device with at least one substantially uniform layer of phosphorous powder matrix made in accordance with the method of claim 3.
